(19) United States
(12) Patent Application Publication
(10) Pub. No.: US 2026/0209600 A1
(43) Pub. Date: Jul. 23, 2026

(54) QUANTUM DOT MATERIAL, PREPARATION METHOD THEREFOR, AND LIGHT-EMISSION MATERIAL FILM

(71) Applicants: TCL Technology Group Corporation, Huizhou, Guangdong (CN); Guangdong Juhua Research Institute of Advanced Display, Guangzhou, Guangdong (CN)

(72) Inventors: Likuan ZHOU, Huizhou, Guangdong (CN); Wenjun HOU, Huizhou, Guangdong (CN); Weiran CAO, Huizhou, Guangdong (CN)

(73) Assignees: TCL Technology Group Corporation, Huizhou, Guangdong (CN); Guangdong Juhua Research Institute of Advanced Display, Guangzhou, Guangdong (CN)

(21) Appl. No.: 19/144,495

(22) PCT Filed: Sep. 26, 2023
(86) PCT No.: PCT/CN2023/121332

§ 371 Date: Jun. 29, 2025

(30) Foreign Application Priority Data
Dec. 30, 2022 (CN) 202211731146.4

(51) Int. Cl. C09K 11/88; B82Y 20/00; B82Y 40/00; C08K 9/02; C09K 11/02; H10K 50/115

(52) U.S. Cl. CPC C09K 11/883; C08K 9/02; C09K 11/02; B82Y 20/00; B82Y 40/00; C08K 2201/011; H10K 50/115

(57) ABSTRACT

Disclosed are a preparation method for a quantum dot, a preparation method therefor, and a light-emission material film. Controlling a dimension of a luminescent core of a core-shell quantum dot to be 10 nm to 20 nm may improve a blue light absorption rate and a light extraction efficiency during a light conversion process, such that an use amount of a quantum dot material in a device may be reduced, thereby saving a material cost. In addition, since the dimension of the luminescent core is larger than an exciton bohr diameter, a binding effect of excitons in a core is greatly improved, thus reducing a probability of excitons being quenched by interface defect states, and improving water-resistance and oxygen-resistance stability of the quantum dot material.

The application claims priority to Chinese Patent Application No. 202211731146.4, filed on Dec. 30, 2022, and entitled “QUANTUM DOT MATERIAL AND PREPARATION METHOD THEREFOR, LIGHT-EMISSION MATERIAL FILM AND PREPARATION METHOD THEREFOR, AND DISPLAY DEVICE”, the entire contents of all of which are incorporated herein by reference.

### TECHNICAL FIELD

The present disclosure relates to a technical field of materials, and in particular to a quantum dot material, a preparation method therefor, and a light-emission material film.

### BACKGROUND

Colloidal semiconductor quantum dots (QDs) have special optical properties, such as size-tunability and narrow emission peaks. By epitaxially growing a shell on a quantum dot core to form a core-shell quantum dot, a fluorescence intensity and a photostability of a quantum dot may be enhanced, broadening application fields of the quantum dot. However, a blue light absorption conversion rate of an existing core-shell quantum dot is low. Compared with perovskite quantum dots of a same weight, core-shell quantum dots provide less light during a light conversion process, requiring 3 to 10 times more core-shell quantum dots per display than perovskite quantum dots. This is because an entire perovskite quantum dot is absorbing blue light, while a core-shell quantum dot based on CdSe, InP, etc have only a luminescent core capable of absorbing blue light, and a shell does not participate in a light conversion process except for passivating and protecting the luminescent core. Therefore, when core-shell quantum dots of a same weight absorb 3 to 10 times less blue light than perovskite quantum dots, an amount of a quantum dot material required per display increases by 3 to 10 times, resulting in a high device cost.

Therefore, how to improve a blue light absorption conversion rate of a core-shell quantum dot, reduce an amount of a quantum dot material used, and thereby reduce a cost is crucial to a promotion of a commercial application process of the quantum dot material.

### Technical Solutions

Therefore, the present disclosure provides a quantum dot material, a preparation method therefor, and a light-emission material film.

An embodiment of the present disclosure provides a preparation method for a quantum dot material, including steps of:
mixing a cationic precursor solution and an anionic precursor solution to form a seed crystal;
ripening the seed crystal to form a luminescent core with a diameter in a range of 10 to 20 nm; and
forming at least one shell layer wrapping the luminescent core.

Optionally, a formation temperature of the seed crystal ranges from 280° C. to 310° C.

Optionally, a temperature of the ripening ranges from 340° C. to 380° C.

Optionally, a time of the ripening ranges from 1 hour to 12 hours.

Optionally, a formation of the cationic precursor solution includes: mixing a cationic precursor, a coordinating solvent including a carboxyl group, and a non-coordinating solvent, where a molar ratio of cations in the cationic precursor to the coordinating solvent ranges from 1:1 to 10, and a volume ratio of the coordinating solvent to the non-coordinating solvent ranges from 1:1 to 5:1.

Optionally, the cationic precursor includes multiple cations.

Optionally, the multiple cations include a first cation and a second cation, where a molar ratio of the first cation to the second cation ranges from 1:20 to 1:100, and an activity of the second cation is lower than an activity of the first cation under a same reaction condition.

Optionally, after forming the luminescent core and before forming the shell layer, the preparation method further includes: adding an active substance selected from one or more of an amine compound, a halogen salt, and a phosphine compound to a reaction system.

Optionally, the amine compound may be selected from but not limited to propylamine and octylamine, the halogen salt may be selected from but not limited to ZnCl₂, NH₄Cl, NH₄Br, and KCl, and the phosphine compound may be selected from but not limited to diphenylphosphine and chlorodiphenylphosphine.

Optionally, the coordinating solvent including a carboxyl group is selected from at least one of a saturated fatty acid having a carbon chain length of 18 to 25 and an unsaturated fatty acid having a carbon chain length of 18 to 25.

Optionally, the coordinating solvent including a carboxyl group is selected from oleic acid, linoleic acid, linolenic acid, arachidonic acid, eicosanic acid, stearic acid, nonadecanic acid, pentacosanoic acid, behenic acid, or henicosanoic acid.

Optionally, the non-coordinating solvent is selected from at least one of a substituted or unsubstituted alkane having 10 to 22 carbon atoms, a substituted or unsubstituted alkene having 10 to 22 carbon atoms, a substituted or unsubstituted ether compound having 10 to 22 carbon atoms, and a substituted or unsubstituted aromatic compound having 6 to 10 ring atoms.

Accordingly, an embodiment of the present disclosure provides a quantum dot material including:
a luminescent core with a diameter in a range of 10 to 20 nm; and
at least one shell layer wrapping the luminescent core.

Optionally, a total thickness of the shell layer ranges from 4 nm to 8 nm.

Optionally, a material of the luminescent core is selected from at least one of CdSe, CdS, CdTe, CdSeTe, CdZnS, ZnTe, CdSeS, InP, InAs, InZnP, InGaP, and InGaN.

Optionally, a material of the shell layer is selected from at least one of CdS, CdSeS, CdZnS, CdZnSeS, ZnSe, ZnS, and ZnSeS.

An embodiment of the present disclosure provides a light-emission material film including a quantum dot material, a photoinitiator and a resin in a mass ratio of 8-15:2-5:80-90;
wherein the quantum dot material includes a luminescent core with a diameter in a range of 10 to 20 nm and at least one shell layer wrapping the luminescent core.

Optionally, the photoinitiator is selected from at least one of benzoin and a derivative thereof, benzoyl and a derivative thereof, an α-hydroxyketone derivative, an α-aminoketone derivative, an acylphosphine oxide, and titanocene.

Optionally, the resin is selected from at least one of PMMA, PVDF, PU, and PET.

Optionally, the benzoyl and a derivative thereof are selected from at least one of BDK and an α-hydroxyketone derivative.

Compared with the prior art, the present disclosure includes the following beneficial effects: in a process of researching a quantum dot material, inventors discovered that a luminescent core as a “light absorption-light emission” main body in quantum dot photoconversion applications, a dimension of a luminescent core exhibits an inverse relationship with an amount of the quantum dot material required. That is, the larger the dimension of the luminescent core, the more sufficient an absorption of excitation light, and the stronger a red light or a green light. Conversely, to absorb a same light flux of exciting light, a smaller luminescent core requires a greater amount of a photoconversion material. Based on this, the present disclosure provides a method for preparing a quantum dot material having a large-dimension luminescent core. Compared with an existing core-shell quantum dot, such as a binary system quantum dot (a diameter of a luminescent core is less than or equal to 5 nm) and an alloy system quantum dot (a diameter of a luminescent core is less than or equal to 8 nm), a dimension of the luminescent core of the core-shell quantum dot prepared by the preparation method provided by the present disclosure ranges from 10 nm to 20 nm. A volume of such large-dimension luminescent core is at least 8 times that of the binary system quantum dot and nearly 2 times that of the alloy system quantum dot. Therefore, a quantum dot material with a large-dimension luminescent core has a larger proportion of effective luminescent volume, so that a blue light absorption rate and a light emission rate of a converted light in a light conversion process may be improved, and an amount of the quantum dot material used in a device may be effectively reduced, thereby saving a material cost. In addition, the dimension of the luminescent core is larger than an exciton bohr diameter, a binding effect of excitons in a core is effectively improved, thus reducing a probability of excitons being quenched by interface defect states, and improving water-resistance and oxygen-resistance stability of the quantum dot material.

### BRIEF DESCRIPTION OF THE DRAWINGS

In order to illustrate technical solutions in embodiments of the present disclosure more clearly, accompanying drawings involved in a description of the embodiments may be briefly described below. It may be apparent that the accompanying drawings in the following description are merely some of the embodiments of the present disclosure, and other drawings may be obtained according to these drawings for those skilled in the art without involving any inventive effort.

FIG. 1 is a schematic diagram of a light conversion process of a quantum dot material.

FIG. 2 is an ultraviolet-visible absorption spectrum test curve of a quantum dot material.

FIG. 3 is a flowchart of a preparation method for a quantum dot in the present disclosure.

### DETAILED DESCRIPTION OF EMBODIMENTS

Embodiments of the present disclosure may be described clearly and fully below in connection with accompanying drawings in embodiments of the present disclosure. It may be apparent that the embodiments described are merely a part of embodiments of the present disclosure, rather than all the embodiments. Based on the embodiments in the present disclosure, all other embodiments obtained by a person skilled in the art without involving any inventive effort are within the scope of the present disclosure.

Technical solutions provided by the present disclosure may be described in detail below. An order of description of the following embodiments is not intended to limit a preferred order of embodiments. In addition, in a description of the present disclosure, a term “including/include(s)” means “including but being not limited to/include(s) but is not limited to”. Each embodiment of the present disclosure may be presented in a form of range. It should be understood that a description in a form of range is merely for convenience and brevity, and should not be construed as a limitation on a scope of the present disclosure. Accordingly, it should be considered that a recited range description has specifically disclosed all possible subranges, as well as a single numerical value within that range.

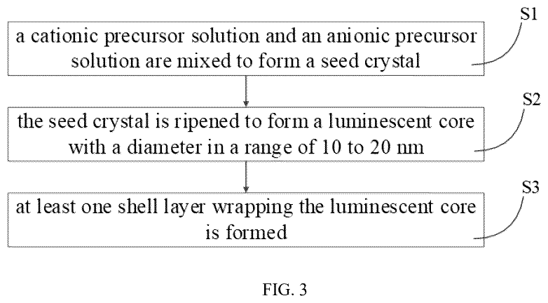

An embodiment of the present disclosure provides a preparation method for a quantum dot material. Referring to FIG. 3, the preparation method includes:
a cationic precursor solution and an anionic precursor solution are mixed to form a seed crystal;
the seed crystal is ripened to form a luminescent core with a diameter in a range of 10 to 20 nm; and
at least one shell layer wrapping the luminescent core is formed.

A formation of a large-dimension luminescent core may be regulated through a seed crystal stage and a ripen ripening stage: (1) by reducing a reaction activity of a cationic precursor in a seed crystal formation stage, a number of seed crystals formed is decreased; (2) in a ripening stage, process conditions are adjusted to improve an activity of an anionic precursor or a cationic precursor and/or prolong a ripening time, promoting a reaction to proceed in a forward direction, that is, a conversion rate of a precursor to the luminescent core is increased to obtain a large-dimension luminescent core. Subsequently, the shell layer is epitaxially grown. By passivating a surface of a quantum dot through shell layer growth, a core-shell quantum dot material with good stability is obtained.

Furthermore, in order to achieve a low precursor activity condition required for a seed crystal formation stage, in some embodiments, a formation temperature of the seed crystal may range from 280° C. to 310° C. Under such a lower temperature condition, it is possible to form an alloying seed crystal to achieve a purpose of increasing a dimension of the luminescent core, while ensuring a low precursor activity, thereby ensuring a smaller number of seed crystals formed.

A ripening process is a process of “dissolution-regrowth” of a quantum dot, that is, in a reaction system, a small-dimension quantum dot undergo a decomposition reaction in a coordinating solvent including a carboxyl group, and a decomposed component further grows. In some embodiments, a temperature of ripening ranges from 340° C. to 380° C. Under such a higher temperature condition, it is beneficial for the coordinating solvent including a carboxyl group to decompose the small-dimension quantum dot and promote a growth of a crystal core.

In some embodiments, a time of ripening ranges from 1 hour to 12 hours.

In order to ensure that sufficient precursors participate in a growth of the seed crystal during a ripening process, in a reaction system, the cationic precursor may be excessively provided in a reaction preparation stage, or the cationic precursor may be supplemented in a ripening stage. When the cationic precursor is provided excessively, in some embodiments, a formation of the cationic precursor solution includes: a cationic precursor, a coordinating solvent including a carboxyl group, and a non-coordinating solvent are mixed. A molar ratio of cations in the cationic precursor to the coordinating solvent ranges from 1:1 to 10, and a volume ratio of the coordinating solvent to the non-coordinating solvent ranges from 1:1 to 5:1. When the cationic precursor includes multiple cations (generally including two types, M1 and M2, with sequentially decreasing reaction activity under a same condition), a component with a lower metal cation reaction activity needs to be in excess, and a molar ratio of M1 to M2 may range from 1:20 to 1:100. A supplementation amount used in the ripening stage may be converted based on the above data. In addition, this scheme increases a proportion of the coordinating solvent including a carboxyl group to reduce a reactivity of metal cations, thereby ensuring that the number of seed crystals in an initial stage of formation is decreased. In an above ratio, an amount used is inversely proportional to a carbon chain length of the coordinating solvent.

Furthermore, the coordinating solvent including a carboxyl group is generally a solvent capable of participating in a coordination of metal cations, and may be selected from at least one of a saturated fatty acid having a carbon chain length of 18 to 25 and an unsaturated fatty acid having a carbon chain length of 18 to 25, for example, oleic acid, linoleic acid, linolenic acid, arachidonic acid, eicosanic acid, stearic acid, nonadecanic acid, pentacosanoic acid, behenic acid, henicosanoic acid, or the like. The non-coordinating solvent is selected from at least one of a substituted or unsubstituted alkane having 10 to 22 carbon atoms, a substituted or unsubstituted alkene having 10 to 22 carbon atoms, a substituted or unsubstituted ether compound having 10 to 22 carbon atoms, and a substituted or unsubstituted aromatic compound having 6 to 10 ring atoms, for example, octadecene, hexadecene, paraffin oil, or the like.

In some embodiments, after forming the luminescent core and before forming the shell layer, the preparation method further includes: an active substance selected from one or more of an amine compound, a halogen salt, and a phosphine compound is added to a reaction system. Adding the active substance may also enhance an activity of a metal cation precursor, promote an equilibrium to shift in a forward direction, and thus facilitate an increase in a dimension of the luminescent core. The amine compound may be selected from but not limited to propylamine and octyla-mine, the halogen salt may be selected from but not limited to ZnCl₂, NH₄Cl, NH₄Br, and KCl, and the phosphine compound may be selected from but not limited to diphe-nylphosphine and chlorodiphenylphosphine. The amine compound and the halogen salt improve a crystal plane activity of the luminescent core by providing ligands, while the phosphine compound activate metal cations by coordinating or bonding with the metal cations. Although effects are different, the amine compound, the halogen salt, and the phosphine compound may all promote the equilibrium to shift in the forward direction, which is conducive to increasing the dimension of the luminescent core.

Additionally, the present disclosure provides a quantum dot material including:
a luminescent core with a diameter in a range of 10 to 20 nm; and
at least one shell layer wrapping the luminescent core.

The diameter of the luminescent core may be, for example, 10 nm, 12 nm, 13 nm, 15 nm, 16 nm, 18 nm, or 19 nm.

In some embodiments, a total thickness of the shell layer ranges from 4 nm to 8 nm, such as 5 nm, 6 nm, or 7 nm. This thickness range not only provides a good passivation effect to ensure a fluorescence stability of the quantum dot material, but also avoids an increase in the number of defect states caused by lattice stress from excessively thick growth of the shell layer, resulting in a decrease of a fluorescence quantum yield. On a premise of meeting a total shell thickness requirement, a thickness of each shell layer may range from 1 nm to 5 nm.

In some embodiments, a material of the luminescent core is selected from at least one of CdSe, CdS, CdTe, CdSeTe, CdZnS, ZnTe, CdSeS, InP, InAs, InZnP, InGaP, and InGaN. A material of the shell layer is selected from at least one of CdS, CdSeS, CdZnS, CdZnSeS, ZnSe, ZnS, and ZnSeS.

Additionally, the present disclosure also provides a light-emission material film including a quantum dot material, a photoinitiator and a resin in a mass ratio of 8-15:2-5:80-90.

The quantum dot material includes a luminescent core with a diameter in a range of 10 to 20 nm and at least one shell layer wrapping the luminescent core.

The light-emission material film is a photoluminescent film that may be applied in a backlight conversion display technology, including an optical film, a QDCF, and a QDCC.

In some embodiments, the photoinitiator is selected from at least one of benzoin (BE) and a derivative thereof, benzoyl and a derivative thereof, an α-hydroxyketone derivative, an α-aminoketone derivative, an acylphosphine oxide, and titanocene. The resin is selected from at least one of PMMA, PVDF, PU, and PET. Furthermore, the benzoyl and the derivative thereof may be, for example, BDK. The α-hydroxyketone derivative may be, for example, a product with a model number of Darocur 1173, Irgacure 184, or Irgacure 2959. The α-aminoketone derivative may be, for example, a product with a model number of Irgacure 907, or Irgacure 369. The acylphosphine oxide may be, for example, a product with a model number of TEPO, Darocur TPO, or Irgacure 819. The titanocene may be, for example, a product with a model number of 784.

Additionally, the present disclosure also provides a method for preparing the light-emission material film mentioned above. The method includes: the quantum dot material, the photoinitiator, the resin and a solvent are mixed, and then a film is formed by curing.

A mass ratio of the quantum dot material, the photoinitiator and the resin is 8-15: 2-5:80-90. The quantum dot material includes a luminescent core with a diameter in a range of 10 to 20 nm and at least one shell layer wrapping the luminescent core.

In some embodiments, a film curing process may be performed under a light-light-shielding condition. A curing method may be photocuring, and a curing time may range from 5 minutes to 30 minutes. Furthermore, the photocuring may be achieved via an ultraviolet light irradiation, where a wavelength of an ultraviolet light may range from 250 nm to 420 nm.

Furthermore, a step of mixing the quantum dot material, the photoinitiator, the resin and the solvent, and then curing to form a film may include: the quantum dot material, the photoinitiator, the resin and the solvent are mixed at a rotational speed in a range of 1000 rmp to 2000 rmp for 30 minutes to 1 hour, followed by a partial solvent removal under a vacuum condition to obtain a colloidal solution, then the colloidal solution is coated under a protective gas atmosphere, followed by a remaining solvent removal under a condition of 500 pa to 2000 pa and 25° C. to 50° C. to form a film, and finally, a photocuring process is performed for 5 minutes to 30 minutes to obtain a light-emission material film with a thickness in a range of 15 m to 40 m.

The solvent used in the method for preparing the light-emission material film may be a non-polar solvent capable of dissolving the quantum dot material, including but being not limited to toluene, xylene, chloroform, and an alkane solvent. Removing part of the solvent during a process reduces a fluidity of the colloidal solution, so as to facilitate deposition into a film. A degree of solvent removal may ensure that a viscosity of the colloidal solution at room temperature (in a range of 20° C. to 35° C., preferably 25° C.) ranges from 6 centipoise (cp) to 20 centipoise (cp). A protective gas may be nitrogen or an inert gas (e.g. argon).

Additionally, the present disclosure also provides a display device including a substrate, an emission structure layer, and a light conversion layer, where the light conversion layer includes the light-emission material film described above or a light-emission material film prepared by the method described above.

The display device may be any electronic product with a display function, including but being not limited to a smartphone, a tablet computer, a notebook computer, a digital camera, a digital video camera, a smart wearable device, a smart weighing electronic scale, a vehicle display, a television or an electronic book. The smart wearable device may be, for example, a smart bracelet, a smart watch, a virtual reality helmet, or the like.

### Example 1

The present embodiment provides a red quantum dot material of CdZnSe/ZnSe/ZnS and a preparation method therefor. The preparation method includes the following steps S1 to S4.

In step S1, 10 mmol of selenium powder and 10 mL of TOP were mixed to prepare a Se/TOP anion precursor solution with a concentration of 1 mol/L, and 10 mmol of sulfur and 10 mL of TOP were mixed to prepare a S/TOP anion precursor solution with a concentration of 1 mol/L.

In step S2, 0.2 mmol of cadmium oxide, 5 mmol of zinc acetate, 15 mL of stearic acid (a coordinating solvent) and 5 mL of paraffin oil (a non-coordinating solvent) were placed into a three-neck flask and heated to 100° C., and then vacuum was applied. After a complete removal of water and oxygen, argon gas was introduced, and a temperature was raised to 300° C. Once the temperature was stabilized, 0.5 mL of the Se/TOP anion precursor solution with a concentration of 1 mol/L was injected into a reaction system. After maintaining for 5 minutes, 2 mL of n-octylamine (an active substance) was supplemented into the reaction system, the temperature was raised to 350° C., and a luminescent core of CdZnSe was obtained by continuing ripening for 2 hours.

In step S3, the temperature of the reaction system was dropped down to 280° C., and then 1 mL of the Se/TOP anionic precursor solution and 1.5 mL of the S/TOP anionic precursor solution were added to the reaction system to grow a shell layer of ZnSe/ZnS.

In step S4, after a reaction was completed and a system was cooled to room temperature, the quantum dot material was obtained through three cycles of precipitation and redissolution using n-heptane as a solvent and ethanol as a non-solvent.

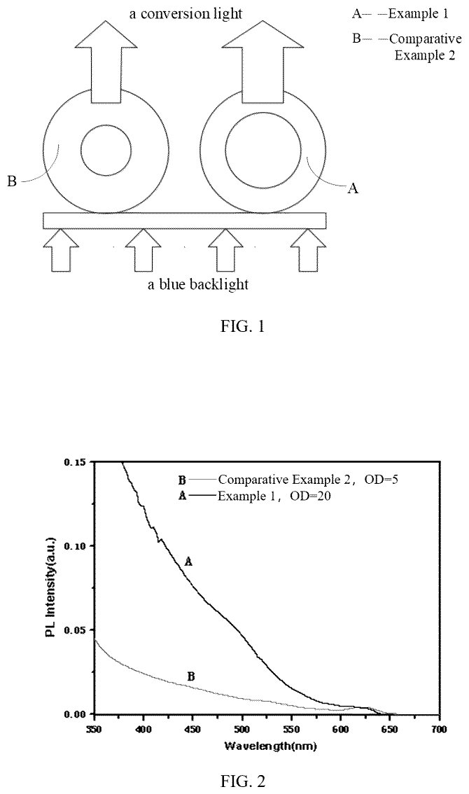

A light conversion process of a quantum dot material of CdZnSe/ZnSe/ZnS prepared in the present embodiment is shown in FIG. 1.

The present embodiment also provides a method for preparing a light-emission material film including the quantum dot material, including the following steps.

According to parts by weight, 3 parts of the quantum dot material, 7 parts of Darocur TPO and 90 parts of PMMA were dissolved in xylene and trimethylbenzene (a volume ratio was 1:1), and were mixed by a Cowles disperser at a rotation speed of 1000 rmp for 1 hour, followed by a partial solvent removal under vacuum to form a colloidal solution. The colloidal solution was coated on a glass by a coating machine under an argon atmosphere. A remaining solvent was slowly removed under a condition of 1000 pa and 50° C. to form a film. The film was then irradiated for 18 minutes at a distance of 10 cm under a 10 W 365 nm ultraviolet lamp and an 80 W mercury lamp to induce crosslinking and curing, so as to obtain a light-emission material film with a thickness of 20 m.

### Example 2

The present embodiment provides a green quantum dot material of CdZnSeS/CdZnS/ZnS and a preparation method therefor. The preparation method includes the following steps S1 to S4.

In step S1, 10 mmol of selenium powder and 10 mL of TOP were mixed to prepare a Se/TOP anion precursor solution with a concentration of 1 mol/L. 10 mmol of sulfur and 10 mL of TOP were mixed to prepare a S/TOP anion precursor solution with a concentration of 1 mol/L. 5 mmol of cadmium oxide, 5 mL of stearic acid and 20 mL of paraffin oil were placed into a three-neck flask and heated to 100° C., and then vacuum was applied, after a complete removal of water and oxygen, argon gas was introduced, and a temperature was raised to 220° C., so as to obtain a Cd(OA)₂ precursor solution with a concentration of 0.2 mol/L.

In step S2, 0.2 mmol of cadmium oxide, 5 mmol of zinc acetate, 15 mL of stearic acid (a coordinating solvent) and 5 mL of paraffin oil (a non-coordinating solvent) were placed into a three-neck flask and heated to 100° C., and then vacuum was applied. After a complete removal of water and oxygen, argon gas was introduced, and a temperature was raised to 290° C. Once the temperature was stabilized, 0.2 mL of the Se/TOP anion precursor solution with a concentration of 1 mol/L and 0.2 mL of the S/TOP anion precursor solution with a concentration of 1 mol/L were injected into a reaction system. After maintaining for 5 minutes, 5 mL of oleic acid (an active substance) was supplemented into the reaction system, the temperature was raised to 360° C., and a luminescent core of CdZnSeS was obtained by continuing ripening for 1.5 hours.

In step S3, the temperature of the reaction system was dropped down to 280° C., and then 2.5 mL of the Cd(OA)₂ precursor solution with a concentration of 0.2 mol/L and 1.5 mL of the S/TOP anionic precursor solution were added to the reaction system to grow a shell layer of CdZnS. The temperature was maintained, and 2 mL of the S/TOP anion precursor solution was continuously added dropwise to grow a shell layer of ZnS.

Step S4 was the same as step S4 in Example 1.

The present embodiment also provides a method for preparing a light-emission material film including the quantum dot material, including the following steps.

According to parts by weight, 4 parts of the quantum dot material, 5 parts of Irgacure 819 and 91 parts of PVDF were dissolved in DMF, and were mixed by a Cowles disperser at a rotation speed of 2000 rmp for 1 hour, followed by a partial solvent removal under vacuum to form a colloidal solution. The colloidal solution was coated on a glass by a coating machine under an argon atmosphere. A remaining solvent was slowly removed under a condition of 500 pa and 25° C. to form a film. The film was then irradiated for 13 minutes at a distance of 10 cm under a 10 W 440 nm ultraviolet lamp and an 80 W white LED lamp to induce crosslinking and curing, so as to obtain a yellow light-emission material film with a thickness of 30 m.

### Comparative Example 1 (Thin Shell Layer)

The present comparative embodiment provides a red quantum dot material of CdZnSe/ZnSe/ZnS and a preparation method therefor. The preparation method includes the following steps S1 to S4.

Step S1 was the same as step S1 in Example 1.

In step S2, 0.2 mmol of cadmium oxide, 3 mmol of zinc acetate, 5 mL of stearic acid and 15 mL of paraffin oil were placed into a three-neck flask, then were heated to 100° C., and then vacuum was applied. After a complete removal of water and oxygen, argon gas was introduced, and a temperature was raised to 320° C. Once the temperature was stabilized, 0.5 mL of the Se/TOP anion precursor solution with a concentration of 1 mol/L was injected into a reaction system. The temperature was maintained, and the luminescent core of CdZnSe was obtained by ripening for 30 minutes.

In step S3, the temperature of the reaction system was dropped down to 280° C., and then 1 mL of the Se/TOP anionic precursor solution and 1 mL of the S/TOP anionic precursor solution were added to the reaction system to grow a shell layer of ZnSe/ZnS.

Step S4 was the same as step S4 in Example 1.

The present comparative embodiment also provides a method for preparing a light-emission material film. The method is substantially the same as the method for preparing a light-emission material film in Example 1, except that the quantum dot material used is the quantum dot material prepared in the present comparative embodiment.

### Comparative Example 2 (Thick Shell Layer)

The present comparative embodiment provides a red quantum dot material of CdZnSe/ZnSe/ZnS and a preparation method therefor. The preparation method includes the following steps S1 to S4.

In step S1, 10 mmol of selenium powder and 10 mL of TOP were mixed to prepare a Se/TOP anion precursor solution with a concentration of 1 mol/L. 10 mmol of sulfur and 10 mL of TOP were mixed to prepare a S/TOP anion precursor solution with a concentration of 1 mol/L. 10 mmol of zinc acetate, 10 mL of stearic acid and 10 mL of paraffin oil were placed into a three-neck flask, then were heated to 100° C., and then vacuum was applied, after a complete removal of water and oxygen, argon gas was introduced, and a temperature was raised to 220° C., so as to obtain a Zn(OA)₂ precursor solution with a concentration of 0.5 mol/L.

In step S2, 0.2 mmol of cadmium oxide, 3 mmol of zinc acetate, 5 mL of stearic acid, and 15 mL of paraffin oil were placed into a three-neck flask, then were heated to 100° C., and then vacuum was applied. After a complete removal of water and oxygen, argon gas was introduced, and a temperature was raised to 320° C. Once the temperature was stabilized, 0.5 mL of the Se/TOP anion precursor solution with a concentration of 1 mol/L was injected into a reaction system. The temperature was maintained, and the luminescent core of CdZnSe was obtained by ripening for 20 minutes.

In step S3, the temperature of the reaction system was dropped down to 280° C. Based on an amount required for a shell layer growth, 20 mL of the Zn(OA)₂ precursor solution with a concentration of 0.5 mol/L was added to the reaction system, and then 5 mL of the Se/TOP anionic precursor solution and 3 mL of the S/TOP anionic precursor solution were added to the reaction system to grow a shell layer of ZnSe/ZnS.

Step S4 was the same as step S4 in Example 1.

A light conversion process of a quantum dot material of CdZnSe/ZnSe/ZnS prepared in the present comparative embodiment is shown in FIG. 1.

The present comparative embodiment also provides a method for preparing a light-emission material film. The method is substantially the same as the method for preparing a light-emission material film in Example 1, except that the quantum dot material used is the quantum dot material prepared in the present comparative embodiment.

### Comparative Example 3

The present comparative embodiment provides a green quantum dot material of CdZnSeS/CdZnS/ZnS and a preparation method therefor. The preparation method includes the following steps S1 to S4.

In step S1, 10 mmol of selenium powder and 10 mL of TOP were mixed to prepare a Se/TOP anion precursor solution with a concentration of 1 mol/L. 10 mmol of sulfur and 10 mL of TOP were mixed to prepare a S/TOP anion precursor solution with a concentration of 1 mol/L. 5 mmol of cadmium oxide, 5 mL of stearic acid and 20 mL of paraffin oil were placed into a three-neck flask, then were heated to 100° C., and then vacuum was applied, after a complete removal of water and oxygen, argon gas was introduced, and a temperature was raised to 220° C., so as to obtain a Cd(OA)₂ precursor solution with a concentration of 0.2 mol/L. 10 mmol of zinc acetate, 10 mL of stearic acid and 10 mL of paraffin oil were placed into a three-neck flask, then were heated to 100° C., and then vacuum was applied, after a complete removal of water and oxygen, argon gas was introduced, and a temperature was raised to 220° C., so as to obtain a Zn(OA)₂ precursor solution with a concentration of 0.5 mol/L.

In step S2, 0.2 mmol of cadmium oxide, 5 mmol of zinc acetate, 5 mL of stearic acid and 15 mL of paraffin oil were placed into a three-neck flask, then were heated to 100° C., and then vacuum was applied. After a complete removal of water and oxygen, argon gas was introduced, and a temperature was raised to 320° C. Once the temperature was stabilized, 0.2 mL of the Se/TOP anion precursor solution with a concentration of 1 mol/L and 0.2 mL of the S/TOP anion precursor solution with a concentration of 1 mol/L were injected into a reaction system. The temperature was maintained, and the luminescent core of CdZnSeS was obtained by ripening for 30 minutes.

In step S3, the temperature of the reaction system was dropped down to 280° C. Based on an amount required for a shell layer growth, 5 mL of the Cd(OA)₂ precursor solution with a concentration of 0.2 mol/L and 3 mL of the S/TOP anionic precursor solution were added to the reaction system to grow a shell layer of CdZnS. The temperature was maintained, and 20 mL of the Zn(OA)₂ precursor solution with a concentration of 0.5 mol/L was supplemented into the reaction system, followed by continuous dropping of 5 mL of the S/TOP anionic precursor solution to grow a shell layer of ZnS.

Step S4 was the same as step S4 in Example 1.

The present comparative embodiment also provides a method for preparing a light-emission material film. The method is substantially the same as the method for preparing a light-emission material film in Example 2, except that the quantum dot material used is the quantum dot material prepared in the present comparative embodiment.

Particle sizes and absorbance values of quantum dot materials provided in Examples 1 and 2 and Comparative Examples 1 to 3 were tested, and test results are shown in Table 1. An emission peak (PL), a full width at half maximum (FWHMN), and a photoluminescence quantum yield (PLQY) were measured by a F7000 fluorescence spectrophotometer and a PE 365 UV-visible photometer respectively, and calculated. An absorbance test was to measure an absorbance of the quantum dot material at a same mass concentration (0.2 mg/mL) under a 450 nm excitation light (OD, which was defined as a ratio of an absorption value at 450 nm to an intensity of a first absorption peak) by an ultraviolet-visible absorption spectroscopy, where toluene with a concentration of 5 μg/mL was used as a solvent. Additionally, photostability of quantum dot materials under a blue light excitation was compared.

TABLE 1

| | | | Particle | PLQY | | | |
|---|---|---|---|---|---|---|---|
| | | Dimension | size of | of | | | |
| | | of | quantum | quantum | | | |
| Quantum | | luminescent | dot | dot | | | |
| dot | | core | material | material | PL | FWHM | OD |
| material | Structure | (nm) | (nm) | solution | (nm) | (nm) | (450 nm) |
| Example 1 | CdZnSe/ | 12 | 17 | 90% | 624 | 23 | 20 |
| | ZnSe/ZnS | | | | | | |
| Example 2 | CdZnSeS/ | 14 | 18 | 88% | 530 | 25 | 14 |
| | CdZnS/ZnS | | | | | | |
| Comparative | CdZnSe/ | 5 | 10 | 75% | 625 | 26 | 3.8 |
| Example 1 | ZnSe/ZnS | | | | | | |
| Comparative | CdZnSe/ | 5 | 17 | 80% | 628 | 24 | 5 |
| Example 2 | ZnSe/ZnS | | | | | | |
| Comparative | CdZnSeS/ | 4 | 17 | 72% | 535 | 28 | 4 |
| Example 3 | CdZnS/ZnS | | | | | | |

As can be seen from Table 1, an absorbance OD₄₅₀ at 450 nm absorption of a quantum dot material with a large-dimension luminescent core provided in Example 1 is 4 times higher than that of a quantum dot material in Comparative Example 2 having a same particle size but a different dimension of a luminescent core. An absorbance OD₄₅₀ at 450 nm absorption of a quantum dot material with a large-dimension luminescent core provided in Example 2 is 3.5 times higher than that of a quantum dot material in Comparative Example 3 having a similar particle size but a different dimension of a luminescent core.

Light-emission material films provided in Examples 1 and 2 and Comparative Examples 1 to 3 were subjected to film PLQY and constant temperature aging tests. Test results are shown in Table 2.

TABLE 2

| | PLQY | |
|---|---|---|
| Luminescent film | Before aging | 80° C., 48 h, after aging |
| Example 1 | 70% | 69% |
| Example 2 | 73% | 72% |
| Comparative Example 1 | 40% | 25% |
| Comparative Example 2 | 45% | 40% |
| Comparative Example 3 | 42% | 36% |

As can be seen from Table 2, PLQYs of light-emission material films with large-dimension luminescent cores provided in Examples 1 and 2 may reach 70% and 73%, respectively, while PLQYs of light-emission material films with small-dimension luminescent cores provided in Comparative Examples 1 to 3 range from 40% to 45%. After light-emission material films were stored at 80° C. for 48 hours, PLQYs of light-emission material films in examples hardly decreased, while a PLQY of the light-emission material film provided in Comparative Example 1 decreased by nearly half, and PLQYs of light-emission material films provided in Comparative Examples 2 and 3 also decreased to 40% and 36%, respectively, thereby indicating that a light-emission material film prepared from a quantum dot material having a large-dimension luminescent core has a better stability.

Additionally, under a blue light excitation of a same intensity, light-emission material films provided in Examples 1 and 2 and Comparative Examples 1 to 3 were detected by a spectrometer. It is found that light-emission material films provided in examples have higher luminescence intensities and relatively lower blue light transmittance intensities, indicating that light-emission material films provided in examples have higher blue light absorptions and conversion efficiencies.

In summary, through a measurement and an analysis, in a toluene solvent with a concentration of 5 μg/mL, an OD value of a quantum dot material with a large-dimension luminescent core at 450 nm is 3 to 10 times higher than that of a quantum dot material with a small-dimension luminescent core. Meanwhile, a large-dimension luminescent core exhibits a better crystallinity, and a thinner shell layer may fully passivate dangling bonds on a surface of the luminescent core, thereby reducing the number of defect states caused by a shell dislocation, and a fluorescence quantum yield of the quantum dot material may reach approximately 90%. Additionally, although a shell layer of the quantum dot material with a large-dimension luminescent core is relatively thin, its binding effect on excitons within a core is stronger, leading to a better blue light stability. A light-emission material film prepared by the quantum dot material also exhibits a higher PLQY and a higher stability.

Technical solutions provided by embodiments of the present disclosure have been described in detail above, and specific examples have been applied herein to illustrate principles and embodiments. Descriptions of examples above are provided merely to help understand a method and a core idea of the present disclosure. Meanwhile, for those skilled in the art, based on ideas of the present disclosure, there may be changes in specific embodiments and application scopes. In conclusion, a content of the present specification may not be construed as a limitation to the present disclosure.

1. A preparation method for a quantum dot material, comprising steps of:
mixing a cationic precursor solution and an anionic precursor solution to form a seed crystal;
ripening the seed crystal to form a luminescent core with a diameter in a range of 10 to 20 nm; and
forming at least one shell layer wrapping the luminescent core.

2. The preparation method according to claim 1, wherein a formation temperature of the seed crystal ranges from 280° C. to 310° C.

3. The preparation method according to claim 1, wherein a temperature of the ripening ranges from 340° C. to 380° C.

4. The preparation method according to claim 1, wherein a time of the ripening ranges from 1 hour to 12 hours.

5. The preparation method of claim 1, wherein a formation of the cationic precursor solution comprises: mixing a cationic precursor, a coordinating solvent comprising a carboxyl group, and a non-coordinating solvent; wherein a molar ratio of cations in the cationic precursor to the coordinating solvent ranges from 1:1 to 10, and a volume ratio of the coordinating solvent to the non-coordinating solvent ranges from 1:1 to 5:1.

6. The preparation method of claim 1, wherein the cationic precursor comprises multiple cations.

7. The preparation method of claim 1, wherein the multiple cations comprise a first cation and a second cation, where a molar ratio of the first cation to the second cation ranges from 1:20 to 1:100, and an activity of the second cation is lower than an activity of the first cation under a same reaction condition.

8. The preparation method according to claim 1, wherein after forming the luminescent core and before forming the shell layer, the preparation method further comprises: adding an active substance selected from one or more of an amine compound, a halogen salt, and a phosphine compound to a reaction system.

9. The preparation method according to claim 8, wherein the amine compound is selected from propylamine and octylamine, the halogen salt is selected from ZnCl₂, NH₄Cl, NH₄Br, and KCl, and the phosphine compound may be selected from but not limited to diphenylphosphine and chlorodiphenylphosphine.

10. The preparation method according to claim 5, wherein the coordinating solvent comprising a carboxyl group is selected from at least one of a saturated fatty acid having a carbon chain length of 18 to 25 and an unsaturated fatty acid having a carbon chain length of 18 to 25.

11. The preparation method according to claim 5, wherein the coordinating solvent comprising a carboxyl group is selected from oleic acid, linoleic acid, linolenic acid, arachidonic acid, eicosanic acid, stearic acid, nonadecanic acid, pentacosanoic acid, behenic acid, or henicosanoic acid.

12. The preparation method according to claim 5, wherein the non-coordinating solvent is selected from at least one of a substituted or unsubstituted alkane having 10 to 22 carbon atoms, a substituted or unsubstituted alkene having 10 to 22 carbon atoms, a substituted or unsubstituted ether compound having 10 to 22 carbon atoms, and a substituted or unsubstituted aromatic compound having 6 to 10 ring atoms.

13. A quantum dot material comprising:
a luminescent core with a diameter in a range of 10 to 20 nm; and
at least one shell layer wrapping the luminescent core.

14. The quantum dot material according to claim 13, wherein a total thickness of the shell layer ranges from 4 nm to 8 nm.

15. The quantum dot material according to claim 13, wherein a material of the luminescent core is selected from at least one of CdSe, CdS, CdTe, CdSeTe, CdZnS, ZnTe, CdSeS, InP, InAs, InZnP, InGaP, and InGaN.

16. The quantum dot material according to claim 13, wherein a material of the shell layer is selected from at least one of CdS, CdSeS, CdZnS, CdZnSeS, ZnSe, ZnS, and ZnSeS.

17. A light-emission material film comprising a quantum dot material, a photoinitiator and a resin in a mass ratio of 8-15:2-5:80-90;
wherein the quantum dot material comprises a luminescent core with a diameter in a range of 10 to 20 nm and at least one shell layer wrapping the luminescent core.

18. The light-emission material film according to claim 17, wherein the photoinitiator is selected from at least one of benzoin and a derivative thereof, benzoyl and a derivative thereof, an α-hydroxyketone derivative, an α-aminoketone derivative, an acylphosphine oxide, and titanocene.

19. The light-emission material film according to claim 17, wherein the resin is selected from at least one of PMMA, PVDF, PU, and PET.

20. The light-emission material film according to claim 17, wherein the benzoyl and the derivative thereof are selected from at least one of BDK and an α-hydroxyketone derivative.
